(19) United States
(12) Patent Application Publication
(10) Pub. No.: US 2016/0252347 A1
(43) Pub. Date: Sep. 1, 2016

(54) FILM THICKNESS SENSOR AND MANUFACTURING METHOD THEREOF

(71) Applicants: BOE Technology Group Co., Ltd., Beijing (CN); Ordos Yuansheng Optoelectronics Co., Ltd., Ordos, Inner Mongolia (CN)

(72) Inventor: Ang XIAO, Beijing (CN)

(21) Appl. No.: 14/769,293

(22) PCT Filed: Dec. 3, 2014
(86) PCT No.: PCT/CN2014/092901

§ 371 Date: Aug. 20, 2015

(30) Foreign Application Priority Data
Sep. 18, 2014 (CN) 201410479802.5

(51) Int. Cl. G01B 21/08; C23C 14/06; C23C 14/24

(52) U.S. Cl. CPC G01B 21/08; C23C 14/24; C23C 14/06

(57) ABSTRACT

Disclosed is a film thickness sensor, Mg film or Mg/MgO film is coated on a surface of the film thickness sensor, so that Mg material is easy to attach to the film thickness sensor, and then the waste of Mg material is prevented.

### TECHNICAL FIELD

Embodiments of the present invention relate to a film thickness sensor used in evaporation and a method for manufacturing the same.

### BACKGROUND

In the existing production of OLED panels, usually Mg/Ag alloy is used as a cathode material, and the cathode material is deposited on a glass substrate by evaporation. In order to accurately monitor the film thickness of cathode material deposited on the substrate, a film thickness sensor is disposed on Mg evaporation source and Ag evaporation source, and generally a quartz film thickness sensor is selected.

In general, in order to meet the needs of continuous production, two evaporation sources are disposed in the same metal evaporation chamber, one is a main Mg evaporation source, and the other is a spare Mg evaporation source (each of the two evaporation sources includes a corresponding film thickness sensor). But, Mg vapor is difficult to deposit onto the quartz film thickness sensor, in other words, the rate of depositing Mg vapor onto the quartz film thickness sensor is very slow. Usually, it takes about one hour from the beginning of evaporating Mg vapor on the film thickness sensor until reaching to stable evaporation rate; it causes not only a long time, but also a large waste of Mg material.

### SUMMARY

An embodiment of the present invention provides a film thickness sensor, wherein Mg film or Mg/MgO film is coated on a surface of the film thickness sensor.

As an example, a thickness of the Mg or Mg/MgO film is from 5 nm to 10 nm. For example, the thickness of the Mg or Mg/MgO film is about 8 nm.

As an example, a thickness of MgO film in the Mg/MgO film is from 2 nm to 3 nm.

As an example, a thickness ratio of Mg film and MgO film in the Mg/MgO film is 1: 0.25-1.5. For example, when the thickness of Mg/MgO film is 5 nm, the thickness ratio of Mg film and MgO film is 1: 0.67-1.5; or when the thickness of Mg/MgO film is 8 nm, the thickness ratio of Mg film and MgO film is 1: 0.3-0.6; or when the thickness of Mg/MgO film is 10 nm, the thickness ratio of Mg film and MgO film is 1: 0.25-0.45.

Another embodiment of the present invention provides a method for manufacturing a film thickness sensor, which comprises:

at a temperature of 600-700° C. and in an anaerobic condition of high vacuum, evaporating Mg material on the film thickness sensor to form Mg film thickness sensor; or

at a temperature of 600-700° C. and in an anaerobic condition of high vacuum, evaporating Mg material on the film thickness sensor to form Mg film thickness sensor; exposing the Mg film thickness sensor to an oxygen-containing argon gas at a temperature of 30-45° C. for 60-70 seconds, oxidizing the surface of Mg film partially into MgO to form Mg/MgO film thickness sensor.

As an example, a concentration of oxygen gas in the oxygen-containing argon gas is 5-6%.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiments, without any inventive work, which should be within the scope of the invention.

Embodiments of the present invention provide a film thickness sensor, and Mg or Mg/MgO film is coated on a surface of the film thickness sensor.

The film thickness sensor provided in embodiments of the present invention is a quartz film thickness sensor. Since the main constitute of quartz is silica that belongs to the non-metallic minerals, and the evaporation material Mg belongs to metal elements, Mg material is difficult to attach to the surface of the quartz film thickness sensor during the deposition due to their different properties. In this case, if it is required to achieve steady evaporation rate of Mg material, the evaporation time will be very long, and Mg material will be wasted to a large extent. In the present embodiment, Mg film or Mg/MgO film (Mg film and MgO film) is evaporated on the surface of the quartz film thickness sensor in advance, due to the consistent element properties between evaporation material Mg and Mg film (or Mg/MgO film), Mg is easy to attach to the Mg or Mg/MgO film coated on the surface of the quartz film thickness sensor during evaporation, thus the time taken from the beginning of evaporating Mg vapor on the film thickness sensor until reaching to stable evaporation rate may be reduced, and in turn the waste of Mg material is decreased.

It is appreciated that, in embodiments of the present invention, other films which are easy to attach to Mg material can be evaporated on the surface of the quartz film thickness sensor in advance, such as other elements which belong to the same group IIA as Mg, and elements which belong to groups IIA and IIIA.

Embodiments of the present invention provide a film thickness sensor with Mg or Mg/MgO film coated on the surface of the film thickness sensor. Generally, a quartz film thickness sensor is selected, due to the different own properties between quartz and Mg, the evaporation material Mg is difficult to attach to the quartz material. According to embodiments of the present invention, Mg or Mg/MgO film is evaporated in advance on the surface of the film thickness sensor, thus the time taken from the beginning of evaporating Mg vapor on the film thickness sensor until reaching to stable evaporation rate can be reduced, and the waste of Mg material can be prevented during this time.

In an embodiment of the present invention, the thickness of Mg or Mg/MgO film is from 5 nm to 10 nm. In embodiments of the present invention, whether which one is coated on the surface of the film thickness sensor, the coated thickness is from 5 nm to 10 nm. If the coated thickness is greater than 10 nm, the service life of the film thickness sensor will be significantly reduced. If the coated thickness is less than 5 nm, the uniform film will be formed difficultly on the film thickness sensor during Mg evaporation. In a preferable embodiment of the present invention, the thickness of Mg or Mg/MgO film is 8 nm. The thickness of Mg or Mg/MgO film is set to 8 nm, on one hand, the uniform film can be formed; on the other hand, the amount of Mg material can be reduced while assuring service life of the film thickness sensor.

In another embodiment of the present invention, a thickness of MgO film in the Mg/MgO film is from 2 nm to 3 nm. MgO film in the Mg/MgO film is formed by further oxidation of Mg film, and the thickness of MgO film is from 2 nm to 3 nm. It is favorable to operate the film thickness sensor deposited with Mg film in any environment such as production, storage and transportation, without the concern that Mg could be oxidized into MgO, and then the process complexity and production costs of Mg film thickness sensor are reduced.

In still another embodiment of the present invention, a thickness ratio of Mg film and MgO film in the Mg/MgO film is 1: 0.25-1.5. In embodiments of the present invention, the thickness of Mg/MgO film is from 5 nm to 10 nm, and the thickness of MgO film in the Mg/MgO film is from 2 nm to 3 nm, thus, in this range, the thickness ratio of Mg film and MgO film in the Mg/MgO film is 1: 0.25-1.5. In an alternative embodiment of the present invention, when the thickness of Mg/MgO film is 5 nm, the thickness ratio of Mg film and MgO film is 1: 0.67-1.5; in an alternative embodiment of the present invention, when the thickness of Mg/MgO film is 8 nm, the thickness ratio of Mg film and MgO film is 1: 0.3-0.6; in an alternative embodiment of the present invention, when the thickness of Mg/MgO film is 10 nm, the thickness ratio of Mg film and MgO film is 1: 0.25-0:45. In the above thickness range of Mg/MgO film, Mg/MgO film is prepared according to the thickness ratio of Mg film and MgO film, and then the uniform film can be formed, and the waste of Mg material can be prevented while assuring service life of the film thickness sensor.

Embodiments of the present invention further provide a method for manufacturing the above described film thickness sensor, the method comprises:

at a temperature of 600-700° C. and in an anaerobic condition of high vacuum, evaporating Mg material on the film thickness sensor to form Mg film thickness sensor; or

at a temperature of 600-700° C. and in an anaerobic condition of high vacuum, evaporating Mg material on the film thickness sensor to form Mg film thickness sensor; exposing the Mg film thickness sensor to an oxygen-containing argon atmosphere at a temperature of 30-45° C. for 60-70 seconds, partially oxidizing a surface of the Mg film into MgO to form Mg/MgO film thickness sensor.

In the process of preparing the Mg film thickness sensor, Mg is evaporated on the film thickness sensor in an anaerobic condition, and the condition is very harsh, it is deposited at a temperature of 600-700° C. and in an anaerobic condition of high vacuum, herein the high vacuum is 10⁻⁷ Pa. In the process of preparing Mg/MgO film thickness sensor, the oxidation reaction of Mg is mainly occurred, and the oxidation reaction can be occurred at room temperature. In order to ensure that the temperature at which the oxidation reaction occurred is controllable, the temperature is set at 30-45° C. according to the embodiments of the present invention. It is appreciated that, the Mg/MgO film thickness sensor has more advantages than Mg film thickness sensor in practical production and application, because it is easy to be operated in any environment such as production, storage and transportation, and the process complexity and production costs are lower.

Embodiments of the present invention provide a method for manufacturing the film thickness sensor, because Mg or Mg/MgO film is coated on the surface of the film thickness sensor, evaporation material Mg is easier to attach to the Mg or Mg/MgO film, thus the time taken from the beginning of evaporating Mg vapor on the film thickness sensor until reaching to stable evaporation rate can be reduced, and the waste of Mg material can be prevented during this time. The method is simple, low cost, and prone to be used in large scale production.

In an embodiment of the present invention, an oxygen gas concentration in the oxygen-containing argon gas is 5-6%. In order to ensure that MgO can be formed by the oxidation reaction of Mg, the oxygen gas is mixed with the working argon gas with a ratio of 5-6%. Since the purpose of forming MgO film by oxidizing Mg film is to ensure that the film thickness sensor coated with Mg is not easy to be oxidized in environments such as production, storage and transportation and the MgO film plays the role of a protective layer, the MgO film is not necessary too thick, and appropriate amount of oxygen is mixed with the working argon gas.

The film thickness sensor provided in the invention is illustrated clearly with reference to the specific examples as bellow.

### Example 1

At a temperature of 600° C. and in an anaerobic condition of high vacuum, Mg is evaporated on a film thickness sensor, and Mg film thickness sensor is formed;

the Mg film thickness sensor is exposed to an argon gas containing 5% oxygen gas at a temperature of 30° C. for 60 seconds, a surface of Mg film is partially oxidized into MgO, and a first Mg/MgO film thickness sensor is formed.

### Example 2

At a temperature of 650° C. and in an anaerobic condition of high vacuum, Mg is evaporated on a film thickness sensor, and Mg film thickness sensor is formed;

the Mg film thickness sensor is exposed to an argon gas containing 5.5% oxygen gas at a temperature of 40° C. for 65 seconds, a surface of Mg film is partially oxidized into MgO, and a second Mg/MgO film thickness sensor is formed.

### Example 3

At a temperature of 700° C. and in an anaerobic condition of high vacuum, Mg is evaporated on a film thickness sensor, and Mg film thickness sensor is formed;

the Mg film thickness sensor is exposed to an argon gas containing 6% oxygen gas at a temperature of 45° C. for 70 seconds, a surface of Mg film is partially oxidized into MgO, and a third Mg/MgO film thickness sensor is formed.

Performance Testing

The above film thickness sensors described in Examples 1-3 and a quartz film thickness sensor without Mg or MgO film (referred to as Comparative Example l) are placed in an evaporation equipment, the evaporation rate stability of Mg is tested, and the time taken from the beginning of evaporating Mg vapor until reaching to stable evaporation rate (the difference between four tested target rate is less than ±3%) is measured, the specific results are showed in Table 1.

TABLE 1

| | | | | Comparative |
|---|---|---|---|---|
| | Example 1 | Example 2 | Example 3 | Example 1 |
| Time required | 17 min | 15 min | 18 min | 52 min |

It is obvious from the above results that, because Mg/MgO film is coated on the surface of the film thickness sensor in embodiments of the present invention, Mg material is easier to attach to the Mg/MgO film coated on the quartz film thickness sensor during the evaporation, thus the time taken from the beginning of evaporating Mg vapor on the film thickness sensor until reaching to stable evaporation rate can be reduced, that is, from 52 minutes to 15-18 minutes, and the waste of Mg material can be further reduced during this time.

What is described above is related to the illustrative embodiments of the disclosure only and not limitative to the scope of the disclosure; the scopes of the disclosure are defined by the accompanying claims.

The present application claims the priority of Chinese patent application No. 201410479802.5 filed on Sep. 18, 2014, the disclosure of which is incorporated herein by reference in its entirety.

1. A film thickness sensor, wherein Mg film or Mg/MgO film is coated on a surface of the film thickness sensor.

2. The film thickness sensor according to claim 1, wherein a thickness of the Mg or Mg/MgO film is from 5 nm to 10 nm,

3. The film thickness sensor according to claim 2, wherein the thickness of the Mg or Mg/MgO film is 8 nm.

4. The film thickness sensor according to claim 1, wherein a thickness of MgO film in the Mg/MgO film is from 2 nm to 3 nm.

5. The film thickness sensor according to claim 2, wherein a thickness ratio of Mg film and MgO film in the Mg/MgO film is 1: 0.25-1.5.

6. The film thickness sensor according to claim 5, wherein the thickness of Mg/MgO film is 5 nm, the thickness ratio of Mg film and MgO film is 1: 0.67-1.5.

7. The film thickness sensor according to claim 5, wherein the thickness of Mg/MgO film is 8 nm, the thickness ratio of Mg film and MgO film is 1: 0.3-0,6.

8. The film thickness sensor according to claim 5, wherein the thickness of Mg/MgO film is 10 nm, the thickness ratio of Mg film and MgO film is 1: 0.25-0.45,

9. A method for manufacturing a film thickness sensor, comprising:.
at a temperature of 600-700° C. and in an anaerobic condition of high vacuum, evaporating Mg material on the film thickness sensor to form Mg film thickness sensor; or
at a temperature of 600-700° C. and in an anaerobic condition of high vacuum, evaporating Mg material on the film thickness sensor to form Mg film thickness sensor;
exposing the Mg film thickness sensor to an oxygen-containing argon gas at a temperature of 30-45° C. for 60-70 seconds, oxidizing a surface of Mg film partially into MgO to form Mg/MgO film thickness sensor.

10. The method according to claim 9, wherein a concentration of oxygen gas in the oxygen-containing argon gas is 5-6%.

11. The film thickness sensor according to claim 3, wherein a thickness ratio of Mg film and MgO film in the Mg/MgO film is 1: 0.25-1.5.

12. The film thickness sensor according to claim 4, wherein a thickness ratio of Mg film and MgO film in the Mg/MgO film is 1: 0.25-1.5.
